(19) United States
(12) Patent Application Publication
(10) Pub. No.: US 2026/0299201 A1
(43) Pub. Date: Oct. 1, 2026

(54) OPTOELECTRONIC WAFER BONDING STRUCTURE AND BONDING METHOD, CHIP PACKAGE STRUCTURE AND PACKAGE METHOD

(71) Applicant: JCET Microelectronics (Jiangyin) Co., LTD., Jiangyin (CN)

(72) Inventors: Haijie CHEN, Jiangyin (CN); Jingyu WU, Jiangyin (CN)

(73) Assignee: JCET Microelectronics (Jiangyin) Co., LTD., Jiangyin (CN)

(21) Appl. No.: 19/565,122

(22) Filed: Mar. 12, 2026

(30) Foreign Application Priority Data
Mar. 28, 2025 (CN) 202510381029.7

(51) Int. Cl. G02B 6/13; G02B 6/12; G02B 6/122

(52) U.S. Cl. CPC G02B 6/13; G02B 6/122; G02B 2006/12104

(57) ABSTRACT

An optoelectronic wafer bonding structure and a bonding method, a chip package structure and a package method, are provided. The method includes: providing a photonic integrated circuit wafer including photonic integrated circuit chips, each photonic integrated circuit chip includes first, second, and third areas arranged in sequence along a first direction, where the first area is provided with a conductive structure, and the second area is provided with a waveguide extending along the first direction; forming a trench in the third area, and a sidewall of the trench exposes the waveguide; providing an electronic chip and bonding the electronic chip to an upper surface of one of the photonic integrated circuit chips; arranging a reflective structure within the trench; and filling the trench with a light-transmitting material to form a light-transmitting layer covering the reflective structure.

### CROSS-REFERENCE TO RELATED APPLICATIONS

This application claims the benefit of priority to Chinese Application No. 202510381029.7, filed on Mar. 28, 2025, which is incorporated herein by reference in its entirety.

### TECHNICAL FIELD

The present application relates to the field of chip package, and particularly relates to an optoelectronic wafer bonding structure and a bonding method, a chip package structure, and a package method.

### BACKGROUND

In 2.5D package, a plurality of semiconductor chips manufactured using different process technologies are typically placed side-by-side on an interposer layer, and the interposer acts as a bridge to connect each chip and provide high-speed communication interfaces. With the continuous evolution of advanced package technology, 2.5D package is becoming increasingly widely used; 2.5D package can integrate more functional chips in a limited space, achieving a complete system function within a single package.

### SUMMARY

An optoelectronic wafer bonding structure and a bonding method, a chip package structure, and a package method are provided.

The optoelectronic wafer bonding method, which includes the following steps: providing a photonic integrated circuit wafer, the photonic integrated circuit wafer includes a plurality of photonic integrated circuit chips, each photonic integrated circuit chip has a first area, a second area, and a third area arranged in sequence along a first direction, and the first area is provided with a conductive structure, and the second area is provided with a waveguide extending along the first direction; forming a trench in the third area, and the sidewall of the trench exposes the waveguide; providing an electronic integrated circuit chip and bonding the lower surface of the electronic integrated circuit chip to the upper surface of one of the photonic integrated circuit chips on the photonic integrated circuit wafer, the electronic integrated circuit chip is electrically connected with the conductive structure; arranging a reflective structure within the trench, such that light emitted from the waveguide can be reflected by the reflective structure and then emitted along a second direction, wherein the second direction is perpendicular to the first direction; and filling the trench with a light-transmitting material to form a light-transmitting layer covering the reflective structure, light emitted from the waveguide is reflected by the reflective structure and then emitted along the second direction, and propagates in the light-transmitting layer.

In some embodiments, the conductive structure further includes: a first conductive solder pad arranged on the upper surface of the photonic integrated circuit chip; and a through-silicon-via, one end is electrically connected to the first conductive solder pad, another end extends perpendicular to the upper surface toward the interior of the photonic integrated circuit chip.

In some embodiments, the light-transmitting layer also covers the upper surface of the electronic integrated circuit chip.

In some embodiments, in the step of coating a light-transmitting material within the trench to form a light-transmitting layer, the method further includes the following steps: providing an optical fiber soldering area on the surface of the light-transmitting layer, light emitted from the waveguide is reflected by the reflective structure and then emitted along the second direction, and propagates in the light-transmitting layer to the optical fiber soldering area.

In some embodiments, in the step of arranging a reflective structure within the trench, the method further includes the following steps: providing a reflective structure, the reflective structure includes an inclined surface, and a reflective layer is arranged on the inclined surface; and arranging the reflective structure within the trench, the reflective layer is opposed to the waveguide, such that light emitted from the waveguide can be reflected by the reflective layer and then emitted along the second direction.

In some embodiments, in the step of arranging a reflective structure within the trench, the method further includes the following steps: filling the trench with a polymer base material and performing photolithography to form the reflective structure, and the reflective structure includes an inclined surface, the inclined surface is opposed to the waveguide; and arranging a reflective layer on the inclined surface.

In some embodiments, the reflective layer is a metal layer.

In some embodiments, the method further includes the following steps: providing the plurality of electronic integrated circuit chips, and bonding the lower surfaces of the plurality of electronic integrated circuit chips to the upper surfaces of respective photonic integrated circuit chips on the photonic integrated circuit wafer, respectively, and forming the reflective structure and the light-transmitting layer within the trench of each photonic integrated circuit chip.

In some embodiments, the method further includes the following steps: thinning the lower surface of the photonic integrated circuit wafer, such that another end of the through-silicon-via is exposed from the lower surface of the photonic integrated circuit wafer.

In some embodiments, in the step of thinning the lower surface of the photonic integrated circuit wafer, the method further includes the following steps: bonding an auxiliary wafer on the surface of the light-transmitting layer; thinning the lower surface of the photonic integrated circuit wafer, such that another end of the through-silicon-via is exposed from the lower surface of the photonic integrated circuit wafer; and arranging solder balls on the lower surface of the photonic integrated circuit wafer; removing the auxiliary wafer.

In some embodiments, after the step of thinning the lower surface of the photonic integrated circuit wafer, the method further includes the following steps: dicing the photonic integrated circuit wafer to obtain a plurality of independent optoelectronic wafer bonding structures.

In some embodiments, the light-transmitting layer covers the upper surface of the reflective structure, or the upper surface of the reflective structure is flush with the upper surface of the light-transmitting layer.

In order to solve the above problems, the present disclosure provides an optoelectronic wafer bonding structure, which includes: a photonic integrated circuit chip, the photonic integrated circuit chip has a first area, a second area, and a third area arranged in sequence along a first direction, and the first area is provided with a conductive structure, and the second area is provided with a waveguide extending along the first direction, and the third area is provided with a trench, and the sidewall of the trench exposes the waveguide; an electronic integrated circuit chip, the lower surface of the electronic integrated circuit chip is bonded to the upper surface of the photonic integrated circuit chip, and the electronic integrated circuit chip is electrically connected with the conductive structure; a reflective structure arranged within the trench, so that light emitted from the waveguide may be reflected by the reflective structure and then emitted along a second direction, wherein the second direction is perpendicular to the first direction; and a light-transmitting layer filled within the trench and covering the reflective structure, light emitted from the waveguide is reflected by the reflective structure and then emitted along the second direction, and propagates in the light-transmitting layer.

In some embodiments, the conductive structure further includes: a first conductive solder pad arranged on the upper surface of the photonic integrated circuit chip; and a through-silicon-via, one end is electrically connected to the first conductive solder pad, and another end is exposed from the lower surface of the photonic integrated circuit chip.

In some embodiments, the lower surface of the photonic integrated circuit chip is further provided with solder balls.

In some embodiments, the reflective structure includes an inclined surface, a reflective layer is arranged on the inclined surface, and the reflective layer and the waveguide are arranged opposed to each other, such that light emitted from the waveguide can be reflected by the reflective layer and then emitted along the second direction.

In some embodiments, the light-transmitting layer also covers the upper surface of the electronic integrated circuit chip.

In some embodiments, the light-transmitting layer covers the upper surface of the reflective structure, or the upper surface of the reflective structure is flush with the upper surface of the light-transmitting layer.

In some embodiments, the surface of the light-transmitting layer is also provided with an optical fiber soldering area, and light emitted from the waveguide is reflected by the reflective structure and then emitted along the second direction, and propagates in the light-transmitting layer to the optical fiber soldering area.

A chip package method, which includes the following steps: providing a substrate, the upper surface of the substrate includes a first package area and a second package area; and arranging a chip stacked structure in the first package area, arranging an optoelectronic wafer bonding structure in the second package area, the optoelectronic wafer bonding structure uses the optoelectronic wafer bonding structure described in the present disclosure.

In some embodiments, the method further includes the following steps: forming a molding body on the surface of the substrate, the molding body covers the chip stacked structure and the optoelectronic wafer bonding structure, and exposes the upper surfaces of the chip stacked structure and the optoelectronic wafer bonding structure.

In some embodiments, the molding body of the area corresponding to the reflective structure of the optoelectronic wafer bonding structure is removed to expose the upper surface of the reflective structure.

In some embodiments, the method further includes the following steps: soldering an optical fiber to the optical fiber soldering area.

A chip package structure, which includes: a substrate, the surface of the substrate includes a first package area and a second package area; a chip stacked structure arranged in the first package area; and an optoelectronic wafer bonding structure arranged in the second package area, the optoelectronic wafer bonding structure uses the optoelectronic wafer bonding structure described in the present disclosure.

In some embodiments, it further includes: a molding body formed on the surface of the substrate, the molding body covers the chip stacked structure and the optoelectronic wafer bonding structure and exposes the upper surfaces of the chip stacked structure and the optoelectronic wafer bonding structure; and an optical fiber soldered to the optical fiber soldering area.

It should be understood that the above general description and subsequent detailed description are only exemplary and explanatory, and cannot limit the present disclosure. For technologies, methods, and equipment known to those ordinary skilled in the relevant art, detailed discussions may not be made, but in appropriate circumstances, the technologies, methods, and equipment should be considered as a part of the allowed specification.

### BRIEF DESCRIPTION OF THE DRAWINGS

In order to explain the technical solutions in the specific embodiments of the present disclosure, the accompanying drawings required for the description of the specific embodiments will be briefly introduced below. It is obvious that the accompanying drawings described below are only some specific embodiments of the present disclosure, and for those ordinary skilled in the art, other accompanying drawings can be obtained according to these accompanying drawings without inventive effort.

FIG. 1 is a flowchart of steps of an embodiment of the photoelectric wafer bonding method according to the present disclosure.

FIG. 2 is a process structural schematic diagram of a photonic integrated circuit chip in a photonic integrated circuit wafer provided by an embodiment of the photoelectric wafer bonding method according to the present disclosure.

FIG. 3 is a process structural schematic diagram of forming a trench in the third area of an embodiment of the photoelectric wafer bonding method according to the present disclosure.

FIG. 4 is a process structural schematic diagram of providing an electronic integrated circuit chip and bonding the lower surface of the electronic integrated circuit chip to the upper surface of a photonic integrated circuit chip on the photonic integrated circuit wafer of an embodiment of the photoelectric wafer bonding method according to the present disclosure.

FIG. 5 is a process structural schematic diagram of arranging a reflective structure within the trench of an embodiment of the photoelectric wafer bonding method according to the present disclosure.

FIG. 6 is a process structural schematic diagram of arranging a reflective structure within the trench of another embodiment of the photoelectric wafer bonding method according to the present disclosure.

FIG. 7 is a process structural schematic diagram of forming a light-transmitting layer of an embodiment of the photoelectric wafer bonding method according to the present disclosure.

FIG. 8 is a process structural schematic diagram of thinning the lower surface of the photonic integrated circuit wafer of an embodiment of the photoelectric wafer bonding method according to the present disclosure.

FIG. 9 is a process structural schematic diagram of a photonic bonding structure of another embodiment of the photoelectric wafer bonding method according to the present disclosure.

FIG. 10 is a flowchart of steps of an embodiment of the chip package method according to the present disclosure.

FIG. 11 is a process structural schematic diagram of providing an initial structure of an embodiment of the chip package method according to the present disclosure.

FIG. 12 is a process structural schematic diagram of arranging an optoelectronic wafer bonding structure in a second package area on the surface of the substrate of an embodiment of the chip package method according to the present disclosure.

FIG. 13 is a process structural schematic diagram of forming a molding body on the surface of the substrate of an embodiment of the chip package method according to the present disclosure.

FIG. 14 is a process structural schematic diagram of soldering an optical fiber to the optical fiber soldering area of an embodiment of the chip package method according to the present disclosure.

### DETAILED DESCRIPTION

The technical solutions in the embodiments of the present disclosure will be described below in conjunction with the accompanying drawings. Obviously, the described embodiments are only a part of embodiments of the present disclosure, not all embodiments. Based on the embodiments of the present disclosure, all other embodiments obtained by those skilled in the art without inventive effort are within the protection scope of the present disclosure.

Following the integration of 2.5D package, the throughput of big data requires the participation of integrated photonic integrated circuit wafers, more and more optoelectronic co-package solutions are proposed, and 2.5D is one of the good solution ideas. Through a photonic interposer, chips such as application-specific integrated circuits (ASICs) and memory, etc., can be co-packaged through the interposer, and the interposer can continue to couple with optical devices to achieve big data transmission.

The 2.5D package requires processing on both sides of the package body, but the front surface of the photonic interposer needs to be optically coupled, and the optical coupling area needs to be open, so it is impossible to form a sealed package, resulting in poor reliability of the package body.

Therefore, the inability to seal the front surface of the photonic interposer package and the poor reliability of the package body are the problems that need to be solved at present.

In the optoelectronic wafer bonding structure and the method for bonding the same in the technical solution described herein, the light emission direction is changed by a reflective structure to be vertically upward, and the trench is wrapped by a light-transmitting layer to facilitate the arrangement of molding body during subsequent package processes, so that the package strength is ensured; meanwhile, it can also be ensured during the corresponding processes that the light-emitting area is protected from contamination.

In the chip package structure and package method of the technical solution described herein, a chip-wafer hybrid bonding structure is formed by the electronic integrated circuit chip and the photonic integrated circuit wafer in advance, and during the package process, it can avoid the problem of the electronic integrated circuit chip being incompatible with production lines when used as a 2.5D silicon.

Furthermore, in the optoelectronic wafer bonding structure, the light emission direction is changed by a reflective structure to be vertically upward, and the trench is wrapped by a light-transmitting layer, such that during the package process, the photonic integrated circuit wafer, the electronic integrated circuit chip, and the chip stacked structure can all be protected by molding materials, which significantly increase strength and can also avoid contamination of the light-emitting area during underfill or molding processes.

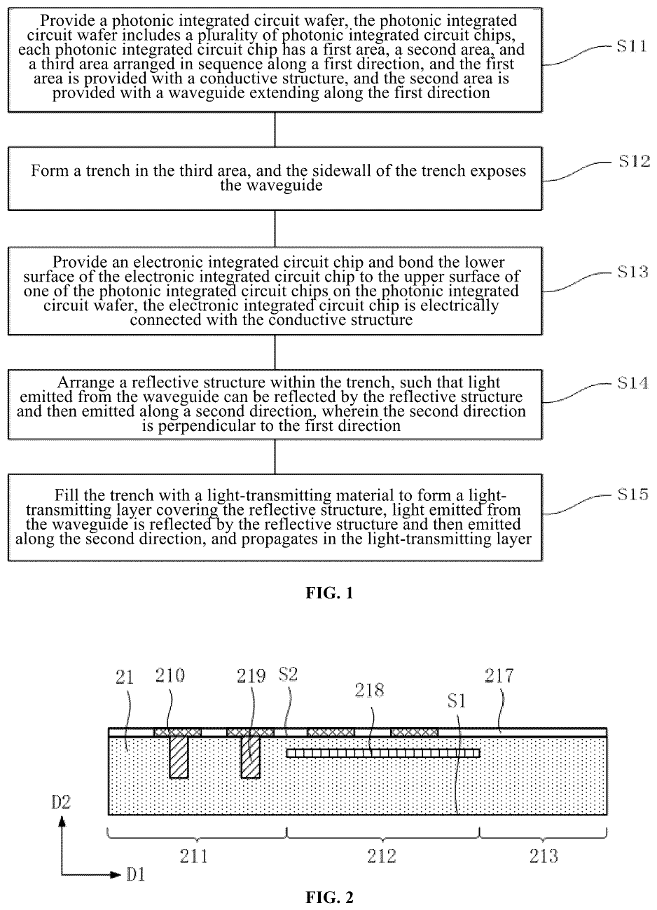

Referring to FIG. 1, it is a flowchart of steps of an embodiment of the photoelectric wafer bonding method according to the present disclosure. As shown in FIG. 1, the optoelectronic wafer bonding method includes the following steps: step S11: providing a photonic integrated circuit wafer, the photonic integrated circuit wafer includes a plurality of photonic integrated circuit chips, each photonic integrated circuit chip has a first area, a second area, and a third area arranged in sequence along a first direction, and the first area is provided with a conductive structure, and the second area is provided with a waveguide extending along the first direction; step S12: forming a trench in the third area, and the sidewall of the trench exposes the waveguide; step S13: providing an electronic integrated circuit chip and bonding the lower surface of the electronic integrated circuit chip to the upper surface of one of the photonic integrated circuit chips on the photonic integrated circuit wafer, the electronic integrated circuit chip is electrically connected with the conductive structure; step S14: arranging a reflective structure within the trench, such that light emitted from the waveguide can be reflected by the reflective structure and then emitted along a second direction, wherein the second direction is perpendicular to the first direction; and step S15: filling the trench with a light-transmitting material to form a light-transmitting layer covering the reflective structure, light emitted from the waveguide is reflected by the reflective structure and then emitted along the second direction, and propagates in the light-transmitting layer.

Referring to FIG. 2 and step S11, a Photonic Integrated Circuit (PIC) wafer is provided, the photonic integrated circuit wafer includes a plurality of photonic integrated circuit chips 21, and each photonic integrated circuit chip 21 has a first area 211, a second area 212, and a third area 213 arranged in sequence along a first direction D1, and the first area 211 is provided with a conductive structure, and the second area 212 is provided with a waveguide 218 extending along the first direction D1.

In order to illustrate the process of bonding an electronic integrated circuit chip to one of the photonic integrated circuit chips on the photonic integrated circuit wafer, only one of the photonic integrated circuit chips on the photonic integrated circuit wafer is depicted in FIGS. 2-8.

However, in the actual bonding method provided by the present disclosure, the electronic integrated circuit chip is a chip formed by dicing the electronic integrated circuit wafer, and the photonic integrated circuit chip is located on the undiced photonic integrated circuit wafer, and the bonding method described in the present disclosure is a chip-wafer hybrid bonding between the electronic integrated circuit chip and the photonic integrated circuit wafer.

In some embodiments, the photonic integrated circuit wafer is an 8-inch wafer (with a diameter of approximately 200 millimeters). 8-inch wafers are widely used in the semiconductor manufacturing field, and have formed mature and efficient production lines, which can integrate a plurality of photonic integrated circuit chips onto the same wafer for mass production. In the optical communication industry, it can meet the large demand for photonic integrated circuits in high-speed optical modules driven by 5G network construction and data center expansion. The 8-inch wafer size is moderate, which is conducive to improving raw material utilization, reducing costs, and can perfectly adapt to existing semiconductor manufacturing processes, and when integrated with other chips or components, it can seamlessly integrate with package processes, and the integration and stability of integrated circuit systems are improved.

In other embodiments, the photonic integrated circuit wafer may also be a 4-inch wafer (with a diameter of approximately 100 millimeters) or a 12-inch wafer (with a diameter of approximately 300 millimeters).

In some embodiments, the conductive structure further includes a first conductive solder pad 210 and a through-silicon-via 219. The first conductive solder pad 210 is arranged on the upper surface S2 of the photonic integrated circuit chip 21; one end of the through-silicon-via 219 is electrically connected to the first conductive solder pad 210, and another end extends perpendicular to the upper surface S2 towards the interior of the photonic integrated circuit chip 21.

In some embodiments, a first dielectric layer 217 is formed on the upper surface S2 of the photonic integrated circuit chip 21, and the first conductive solder pad 210 is on the same layer with the surface of the first dielectric layer 217 and the surface is flush.

That is, the surface of the first conductive solder pad 210 is exposed on the surface of the first dielectric layer 217 to facilitate achieving electrical connection with the electronic integrated circuit chip during the subsequent bonding process with the electronic integrated circuit chip.

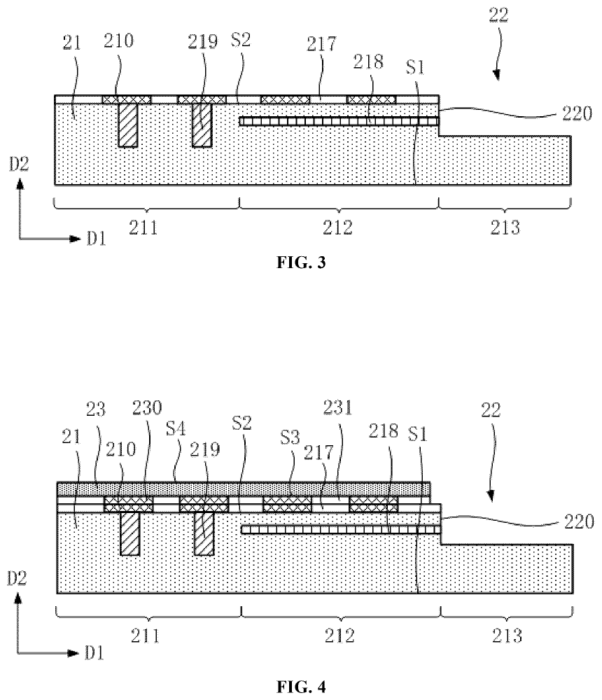

Referring to FIG. 3 and step S12, a trench 22 is formed in the third area 213, and the sidewall 220 of the trench 22 exposes the waveguide 218. In some embodiments, dry etching is used to form the trench 22 in the third area 213.

The trench 22 is used to accommodate a subsequently formed reflective structure, and the waveguide 218 is led out through the sidewall 220, so that the light emitted by the waveguide 218 can propagate to the surface of the reflective structure, and then be reflected by the reflective structure and then emitted along the second direction.

Referring to FIG. 4 and step S13, an electronic integrated circuit chip 23 is provided, and the lower surface S3 of the electronic integrated circuit chip 23 is bonded to the upper surface S2 of the photonic integrated circuit chip 21 of the photonic integrated circuit wafer, and the electronic integrated circuit chip 23 is electrically connected with the conductive structure.

In some embodiments, the electronic integrated circuit chip 23 is a chip formed by dicing an electronic integrated circuit wafer, and the photonic integrated circuit chip 21 is located on the undiced photonic integrated circuit wafer; in step S13, bonding the lower surface S3 of the electronic integrated circuit chip 23 to the upper surface S2 of the photonic integrated circuit chip 21 on the photonic integrated circuit wafer is, in essence, a chip-wafer hybrid bonding between the electronic integrated circuit chip 23 and the photonic integrated circuit wafer.

In some embodiments, the lower surface S3 of the electronic integrated circuit chip 23 is provided with a second conductive solder pad 230 corresponding to the position of the first conductive solder pad 210 on the upper surface S2 of the photonic integrated circuit chip 21, and the electronic integrated circuit chip 23 is bonded to the photonic integrated circuit chip 21 through the electrical connection of the second conductive solder pad 230 with the first conductive solder pad 210.

Furthermore, the lower surface S3 of the electronic integrated circuit chip 23 is provided with a second dielectric layer 231, and the second conductive solder pad 230 is on the same layer with the second dielectric layer 231 and the surface is flush.

That is, the surface of the second conductive solder pad 230 is exposed on the surface of the second dielectric layer 231 to facilitate achieving electrical connection with the photonic integrated circuit chip 21 during the bonding process with the photonic integrated circuit chip 21.

At the hybrid bonding interface, the second conductive solder pad 230 and the first conductive solder pad 210 are bonded to each other to achieve electrical connection of the electronic integrated circuit chip 23 with the photonic integrated circuit chip 21; the first dielectric layer 217 and the second dielectric layer 231 are bonded to each other.

In some embodiments, the thickness of the electronic integrated circuit chip 23 is less than 50 micrometers. The smaller thickness of the electronic integrated circuit chip 23 brings many advantages for the entire integrated circuit system: on the one hand, it greatly reduces the overall volume of the wafer bonding structure, which is in line with the development trend of modern electronic devices constantly pursuing lightweight and miniaturization; on the other hand, thinner chip thickness helps to reduce the path length of signal transmission, thereby reducing losses and delays during signal transmission, significantly improving the processing speed and efficiency during chip operation, and laying a solid foundation for achieving more efficient and faster performance of electronic devices.

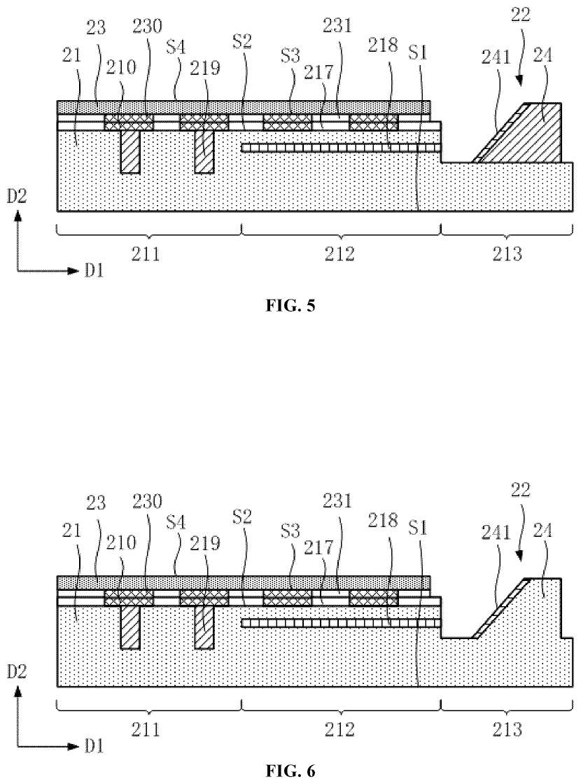

Referring to FIG. 5 and step S14: a reflective structure 24 is arranged within the trench 22, so that the light emitted from the waveguide 218 can be reflected by the reflective structure 24 and then emitted in a second direction D2, wherein the second direction D2 is perpendicular to the first direction D1.

In some embodiments, in the step of providing the reflective structure 24 within the trench 22, the following steps are further included:
(1) Providing a reflective structure 24, the reflective structure 24 includes an inclined surface, and a reflective layer 241 is arranged on the inclined surface.

In the present embodiment, the reflective structure 24 is a prefabricated structure, and the prefabricated structure does not occupy the package production line, and the consistency of the batch prefabricated reflective structure 24 is high.

In some embodiments, the material of the reflective structure 24 is polymer, which facilitates shaping the required shape of the reflective structure 24; the reflective layer 241 is deposited on the inclined surface of the reflective structure 24 through physical vapor deposition (PVD) process or electron beam evaporation (EVP) process, and the reflective layer 241 is a metal layer, and its material may be aluminum (Al), silver (Ag), gold (Au), etc.
(2) Arranging the reflective structure 24 within the trench 22 and the reflective layer 241 is opposed to the waveguide 218, such that the light emitted from the waveguide 218 can be reflected by the reflective layer 241 and then emitted along the second direction D2.

Arranging the prefabricated reflective structure 24 within the trench 22 can save bonding process time, which significantly improves production efficiency and product consistency.

In the present embodiment, the prefabricated reflective structure 24 is fixed within the trench using fixing adhesive.

In other embodiments, in the step of arranging the reflective structure 24 within the trench 22, the following steps are further included:
(1) Filling the trench 22 with a polymer base material and performing photolithography to form the reflective structure 24, and the reflective structure 24 includes an inclined surface, and the inclined surface is opposed to the waveguide 218.

In some embodiments, the material of the reflective structure 24 is polymer, which facilitates shaping the required shape of the reflective structure 24.
(2) Arranging a reflective layer 241 on the inclined surface.

In the present embodiment, the reflective layer 241 is deposited on the inclined surface of the reflective structure 24 through physical vapor deposition (PVD) process or electron beam evaporation (EVP) process. The reflective layer 241 is a metal layer, and its material may be aluminum (Al), silver (Ag), gold (Au), etc.

An inclined surface opposed to the waveguide 218 is arranged within the trench to facilitate receiving light emitted from the waveguide 218, so that the light emitted from the waveguide 218 forms an angle with the surface of the reflective layer 241, and then the original light emission direction is changed after reflection by the reflective layer 241, so that it is emitted along the second direction D2.

Referring to FIG. 6, it is a process structural schematic diagram of arranging a reflective structure within the trench of another embodiment of the photoelectric wafer bonding method according to the present disclosure. As shown in FIG. 6, in the present embodiment, in the step of forming trench 22 in the third area 213, a part of the base material of the third area 213 is retained to form the reflective structure 24, and the reflective structure 24 includes an inclined surface, and the inclined surface is opposed to the waveguide 218. That is, the inclined surface of the reflective structure 24 is formed in one-piece when forming the trench 22, and the base material of the reflective structure 24 is the silicon material of the photonic integrated circuit wafer.

Subsequently, the reflective layer 241 is arranged on the inclined surface of the reflective structure 24, and the lower surface S3 of the electronic integrated circuit chip 23 is bonded to the upper surface S2 of the photonic integrated circuit chip 21 on the photonic integrated circuit wafer, and the structure shown in FIG. 6 is obtained.

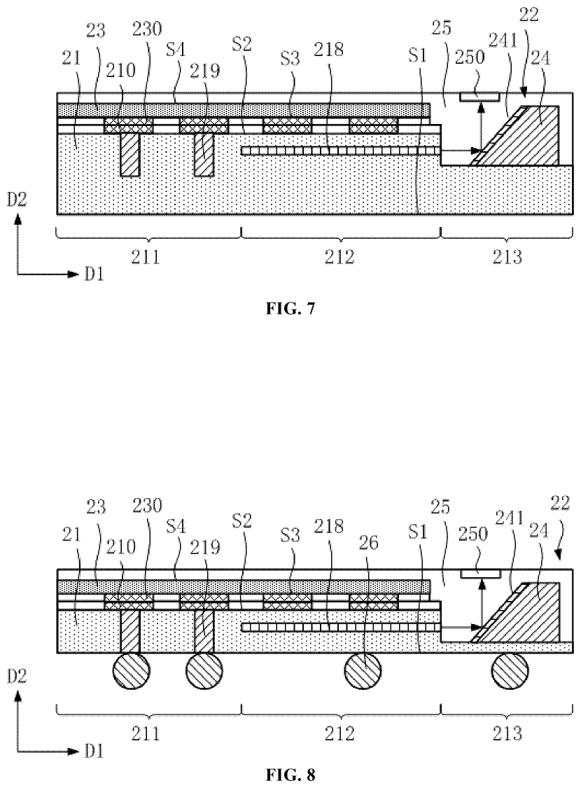

Referring to FIG. 7 and step S15, a light-transmitting material is filled within the trench 22 to form a light-transmitting layer 25 covering the reflective structure 24, and light emitted from the waveguide 218 is reflected by the reflective structure 24 and then emitted along the second direction D2 and propagates within the light-transmitting layer 25. Wherein FIG. 7 continues to depict based on FIG. 5.

In the present embodiment, the light-transmitting material is a transparent organic material, or an inorganic material, or a composite material of the two.

In the present embodiment, the second direction D2 is a vertical upward direction. The light emission direction is changed by the reflective structure 24 to be vertically upward, and the light-emitting area is wrapped by the light-transmitting layer 25 to facilitate the arrangement of the molding body during subsequent package processes, so that the package strength is ensured; meanwhile, it can also be ensured during the corresponding processes that the light-emitting area is protected from contamination.

In some embodiments, the light-transmitting layer 25 also covers the upper surface S4 of the electronic integrated circuit chip 23 to save processes, save process time, and improve production efficiency.

In other embodiments, an opaque material may also be used to cover the upper surface S4 of the electronic integrated circuit chip 23 to save process costs and improve structural stability.

In some embodiments, after forming the light-transmitting layer 25, the following steps are further included: providing an optical fiber soldering area 250 on the surface of the light-transmitting layer 25, light emitted from the waveguide 218 is reflected by the reflective structure 24 and then emitted along the second direction D2 and propagates in the light-transmitting layer 25 to the optical fiber soldering area 250.

The optical fiber soldering area 250 is used to be connected with optical fibers during subsequent package processes, the optoelectronic wafer bonding structure and other optical devices, optical network equipment, etc., are connected together to achieve the integration and construction of optical communication systems.

The process of bonding an electronic integrated circuit chip to one of the photonic integrated circuit chips on the photonic integrated circuit wafer is illustrated in FIGS. 2 to 7 and steps S11 to S15.

Since the photonic integrated circuit wafer includes a plurality of photonic integrated circuit chips 21, in some embodiments, the wafer optoelectronic wafer bonding method further includes the following steps:

Providing the plurality of electronic integrated circuit chips 23, and bonding the lower surfaces S3 of the plurality of electronic integrated circuit chips 23 to the upper surface S2 of respective photonic integrated circuit chip 21 on the photonic integrated circuit wafer, respectively, and forming the reflective structure 24 and the light-transmitting layer 25 within the trench 22 of each photonic integrated circuit chip 21.

In some embodiments, referring to FIGS. 2 to 7 and the process steps shown in steps S11 to S15, the plurality of electronic integrated circuit chips 23 are simultaneously or sequentially bonded to respective photonic integrated circuit chip 21 on the photonic integrated circuit wafer; for a detailed description, reference may be made to the preceding text and it will not be repeated herein.

In some embodiments, the plurality of electronic integrated circuit chips 23 are of the same type of electronic integrated circuit chip; a plurality of electronic integrated circuit chips of the same type are simultaneously bonded to respective photonic integrated circuit chip 21 on the photonic integrated circuit wafer, and the various steps of the chip wafer bonding method are performed simultaneously on the same photonic integrated circuit wafer, which can effectively improve bonding efficiency, thereby increasing productivity and product consistency.

In other embodiments, a plurality of electronic integrated circuit chips 23 of different types may be arranged on the same photonic integrated circuit wafer according to specific process requirements to accommodate more flexible and diverse needs; the plurality of electronic integrated circuit chips of different types are sequentially bonded to respective photonic integrated circuit chip 21 on the photonic integrated circuit wafer.

In some embodiments, the number of electronic integrated circuit chips 23 may correspond to the total number of photonic integrated circuit chips 21 on the photonic integrated circuit wafer.

In other embodiments, the number of electronic integrated circuit chips 23 may be less than the total number of photonic integrated circuit chips 21 on the photonic integrated circuit wafer.

Referring to FIG. 8, after bonding one or more electronic integrated circuit chips 23 to the photonic integrated circuit chips 21 on the photonic integrated circuit wafer, the optoelectronic wafer bonding method further includes the following steps: thinning the lower surface of the photonic integrated circuit wafer, so that another end of the through-silicon-via 219 is exposed from the lower surface of the photonic integrated circuit wafer.

In the present embodiment, the lower surface of the photonic integrated circuit wafer corresponds to and is consistent with the lower surface S1 of the photonic integrated circuit chip 21.

In some embodiments, in the step of thinning the lower surface of the photonic integrated circuit wafer, the following steps are further included: (1) Bonding an auxiliary wafer (not shown in the figures) on the surface of the light-transmitting layer 25; (2) Thinning the lower surface of the photonic integrated circuit wafer to expose another end of the through-silicon-via 219 from the lower surface of the photonic integrated circuit wafer; (3) arranging solder balls 26 on the lower surface of the photonic integrated circuit wafer; (4) Removing the auxiliary wafer.

By thinning the lower surface of the photonic integrated circuit wafer, another end of the through-silicon-via 219 is exposed from the lower surface of the photonic integrated circuit wafer, and the lower surface of the photonic integrated circuit wafer is provided with solder balls 26 electrically connected with the through-silicon-via 219, to connect to external circuits through the solder balls 26, thereby achieving electrical connection with external devices.

In some embodiments, after exposing another end of the through-silicon-via 219 from the lower surface of the photonic integrated circuit wafer by thinning the lower surface of the photonic integrated circuit wafer, the following steps are further included: a single or multiple redistribution layers can be formed on the lower surface of the photonic integrated circuit wafer, and then the solder balls 26 are arranged on the redistribution layer.

Since the above structure is fabricated starting from an entire photonic integrated circuit wafer, in some embodiments, after the step of thinning the lower surface of the photonic integrated circuit wafer, the following steps are further included: dicing the photonic integrated circuit wafer to obtain a plurality of independent optoelectronic wafer bonding structures. Each independent optoelectronic wafer bonding structure is the photovoltaic wafer bonding structure described in the present disclosure.

As shown in FIG. 8, in the present embodiment, the light-transmitting layer 25 covers the upper surface of the reflective structure 24.

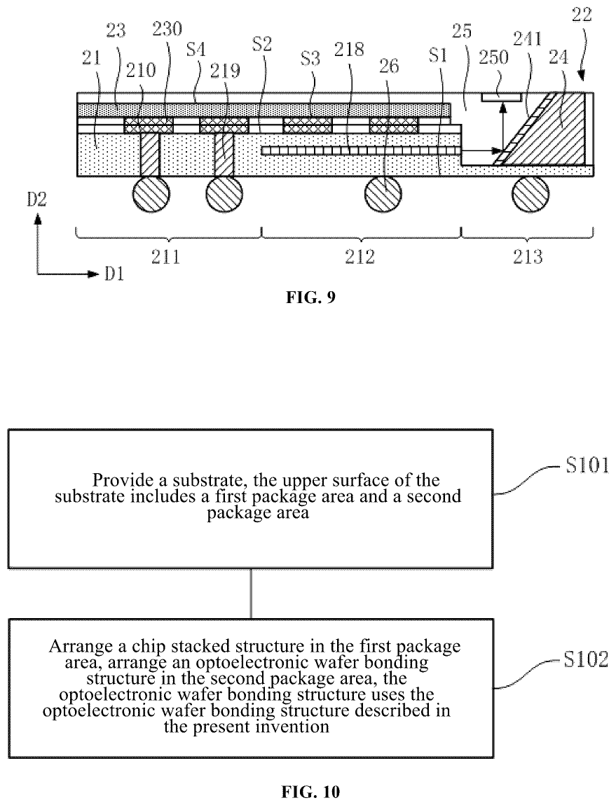

In other embodiments, as shown in FIG. 9, the upper surface of the reflective structure 24 is flush with the upper surface of the light-transmitting layer 25. In some embodiments, the method for forming the light-transmitting layer may also be: (1) Filling the upper surface S4 of the electronic integrated circuit chip 23 and the trench 22 with a transparent material to form the light-transmitting layer 25; (2) Grinding the light-transmitting layer 25 to expose the upper surface of the reflective structure 24; (3) Forming the optical fiber soldering area 250 on the surface of the light-transmitting layer 25.

In the above technical solution, the light emission direction is changed by the reflective structure to be vertically upward, and the light-emitting area is wrapped by the light-transmitting layer to facilitate the arrangement of the molding body during subsequent package processes, so that the package strength is ensured; meanwhile, it can also be ensured during the corresponding processes that the light-emitting area is protected from contamination.

An embodiment of the present disclosure further provides an optoelectronic wafer bonding structure formed using the aforementioned bonding method.

As shown in FIGS. 8 to 9, the optoelectronic wafer bonding structure includes: a photonic integrated circuit chip 21, an electronic integrated circuit chip 23, a reflective structure 24, and a light-transmitting layer 25.

The photonic integrated circuit chip 21 has a first area 211, a second area 212, and a third area 213 arranged in sequence along a first direction D1, and the first area 211 is provided with a conductive structure, and the second area 212 is provided with a waveguide 218 extending along the first direction D1, and the third area 213 is provided with a trench 22, and the sidewall of the trench 22 exposes the waveguide 218.

The lower surface S3 of the electronic integrated circuit chip 23 is hybrid bonded to the upper surface S2 of the photonic integrated circuit chip 21, and the electronic integrated circuit chip 23 is electrically connected with the conductive structure.

The reflective structure 24 is arranged within the trench 22, which enables light emitted from the waveguide 218 to be reflected by the reflective structure 24 and then emitted along a second direction D2, wherein the second direction D2 is perpendicular to the first direction D1.

The light-transmitting layer 25 is filled in the trench 22 and covers the reflective structure 24, and light emitted from the waveguide 218 is reflected by the reflective structure 24 and then emitted along the second direction D2 and propagates in the light-transmitting layer 25.

In the above technical solution, the light emission direction is changed by the reflective structure to be vertically upward, and the trench is wrapped by the light-transmitting layer to facilitate the arrangement of the molding body during subsequent package processes, so that the package strength is ensured; meanwhile, it can also be ensured during the corresponding processes that the light-emitting area is protected from contamination.

In some embodiments, the conductive structure further includes a first conductive solder pad 210 and a through-silicon-via 219. The first conductive solder pad 210 is arranged on the upper surface S2 of the photonic integrated circuit chip 21; one end of the through-silicon-via 219 is electrically connected to the first conductive solder pad 210, and another end is exposed from the lower surface S1 of the photonic integrated circuit chip 21.

In some embodiments, the lower surface S3 of the electronic integrated circuit chip 23 is provided with a second conductive solder pad 230 corresponding to the position of the first conductive solder pad 210 on the upper surface S2 of the photonic integrated circuit chip 21, and the electronic integrated circuit chip 23 is bonded to the photonic integrated circuit chip 21 through the electrical connection of the second conductive solder pad 230 with the first conductive solder pad 210.

Furthermore, the upper surface S2 of the photonic integrated circuit chip 21 is provided with a first dielectric layer 217, and the first conductive solder pad 210 is on the same layer with the surface of the first dielectric layer 217 and the surface is flush; the lower surface S3 of the electronic integrated circuit chip 23 is provided with a second dielectric layer 231, and the second conductive solder pad 230 is on the same layer with the surface of the second dielectric layer 231 and the surface is flush.

At the hybrid bonding interface, the second conductive solder pad 230 and the first conductive solder pad 210 are bonded to each other to achieve electrical connection of the electronic integrated circuit chip 23 with the photonic integrated circuit chip 21; the first dielectric layer 217 and the second dielectric layer 231 are bonded to each other.

In some embodiments, the thickness of the electronic integrated circuit chip 23 is less than 50 micrometers. The smaller thickness of the electronic integrated circuit chip 23 brings many advantages for the entire integrated circuit system: on the one hand, it significantly reduces the overall volume of the wafer bonding structure, which is in line with the development trend of modern electronic devices constantly pursuing lightweight and miniaturization; on the other hand, thinner chip thickness helps to reduce the path length of signal transmission, thereby reducing losses and delays during signal transmission, significantly improving the processing speed and efficiency during chip operation, and laying a solid foundation for achieving more efficient and faster performance of electronic devices.

In some embodiments, the reflective structure 24 includes an inclined surface, and a reflective layer 241 is arranged on the inclined surface, and the reflective layer 241 and the waveguide 218 are arranged opposed to each other, such that light emitted from the waveguide 218 can be reflected by the reflective layer 241 and then emitted along the second direction D2.

In some embodiments, the material of the reflective structure 24 is a polymer.

In some embodiments, the reflective layer 241 is a metal layer, and its material may be aluminum (Al), silver (Ag), gold (Au), etc.

In the present embodiment, the second direction D2 is a vertical upward direction. The light emission direction is changed by the reflective structure 24 to be vertically upward, and the light-emitting area is wrapped by the light-transmitting layer 25 to facilitate the arrangement of the molding body during subsequent package processes, so that the package strength is ensured; meanwhile, it can also be ensured during the corresponding processes that the light-emitting area is protected from contamination.

In some embodiments, the light-transmitting layer 25 also covers the upper surface S4 of the electronic integrated circuit chip 23.

In other embodiments, an opaque material may also be used to cover the upper surface S4 of the electronic integrated circuit chip 23. In some embodiments, the surface of the light-transmitting layer 25 is also provided with an optical fiber soldering area 250, light emitted from the waveguide 218 is reflected by the reflective structure 24 and then emitted along the second direction D2 and propagates in the light-transmitting layer 25 to the optical fiber soldering area 250.

The optical fiber soldering area 250 is used to be connected with optical fibers during subsequent package processes, the optoelectronic wafer bonding structure and other optical devices, optical network equipment, etc., are connected together to achieve the integration and construction of optical communication systems.

In the embodiment shown in FIG. 8, the light-transmitting layer 25 covers the upper surface of the reflective structure 24.

In the embodiment shown in FIG. 9, the upper surface of the reflective structure 24 is flush with the upper surface of the light-transmitting layer 25.

In some embodiments, the lower surface S1 of the photonic integrated circuit chip 21 is also provided with solder balls 26 electrically connected with the through-silicon-via 219, and external circuits are connected through the solder balls 26, thereby achieving electrical connection with external devices.

Based on the same concept, an embodiment of the present disclosure also provides a chip package method.

Referring to FIG. 10, it is a flowchart of steps of an embodiment of the chip package method according to the present disclosure. As shown in FIG. 10, the chip package method includes the following steps: step S101, providing a substrate, the upper surface of the substrate includes a first package area and a second package area; step S102, arranging a chip stacked structure in the first package area, arranging an optoelectronic wafer bonding structure in the second package area, the optoelectronic wafer bonding structure uses the optoelectronic wafer bonding structure described in the present disclosure.

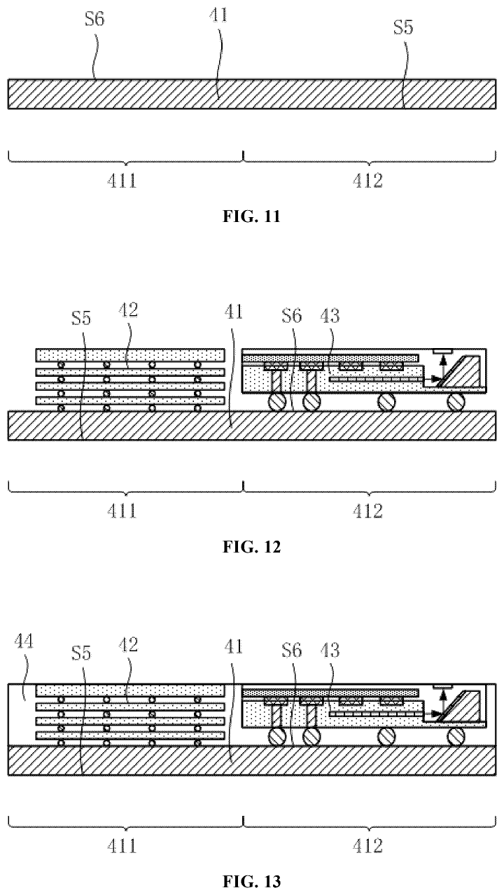

Referring to FIG. 11 and step S101, a substrate 41 is provided, and the upper surface S6 of substrate 41 includes a first package area 411 and a second package area 412.

In some embodiments, the substrate 41 is a silicon interposer. In the chip package method described in the present disclosure, a chip-wafer hybrid bonding structure between the electronic integrated circuit chip and the photonic integrated circuit chip is formed in advance, and during the package process, an additional substrate 41 is used as a 2.5D silicon interposer, which can avoid the problem of the electronic integrated circuit chip being incompatible with production lines when used as a 2.5D silicon.

Referring to step S102 in FIG. 12, a chip stacked structure 42 is arranged in the first package area 411, and an optoelectronic wafer bonding structure 43 is arranged in the second package area 412, and the optoelectronic wafer bonding structure 43 uses the optoelectronic wafer bonding structure illustrated in the embodiments of FIGS. 8 to 9 of the present disclosure; for a detailed description, reference may be made to the preceding text and it will not be repeated herein.

In some embodiments, the chip stacked structure 42 is a memory (Memory). In the present embodiment, the memory is a high-bandwidth memory (HBM).

Referring to FIG. 13, in some embodiments, the chip package method described in the present disclosure further includes the following steps: forming a molding body 44 on the surface of the substrate 41, the molding body 44 covers the chip stacked structure 42 and the optoelectronic wafer bonding structure 43 and exposes the upper surfaces of the chip stacked structure 42 and the optoelectronic wafer bonding structure 43.

The molding body 44, as an important component of the entire package structure, typically uses polymeric materials such as epoxy resin, etc. The main function of the molding body 44 is to significantly enhance the overall strength of the package body and protect components from contamination. In practical applications, electronic products may face various complex usage environments, such as mechanical vibrations, collisions, etc. The molding body 44 can uniformly disperse external forces and prevent damage to internal components such as photonic integrated circuit chips and electronic integrated circuit chips, etc., so that the reliability and durability of the product is greatly improved.

Due to the reflective structure and the light-transmitting layer are arranged in the light-emitting area of the optoelectronic wafer bonding structure 43, the light emission direction is changed by the reflective structure to be vertically upward, and the trench is wrapped by the light-transmitting layer, such that during the package process, the photonic integrated circuit wafer, the electronic integrated circuit chip, and the chip stacked structure 42 can all be protected by molding materials, which significantly increase strength and can also avoid contamination of the light-emitting area during underfill or molding processes.

In some embodiments, the molding body 44 of the area corresponding to the reflective structure of the optoelectronic wafer bonding structure 43 is removed, exposing the upper surface of the reflective structure.

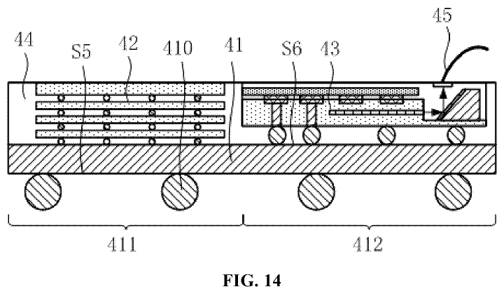

Referring to FIG. 14, in some embodiments, the process further includes the following steps:
(1) Arranging solder balls 410 on the lower surface S5 of the substrate 41 for connecting external circuits, thereby achieving electrical connection with external devices.
(2) Soldering an optical fiber 45 to the optical fiber soldering area 250. The optical fiber soldering area 250 is used to be connected with optical fibers during subsequent package processes, the optoelectronic wafer bonding structure and other optical devices, optical network equipment, etc., are connected together to achieve the integration and construction of optical communication systems.

By completing the above process steps, the chip package structure described in the present disclosure is obtained.

The above technical solution forms a chip-wafer hybrid bonding structure between the electronic integrated circuit chip and the photonic integrated circuit wafer in advance, and during the package process, it can avoid the problem of the electronic integrated circuit chip being incompatible with production lines when used as a 2.5D silicon.

Furthermore, in the optoelectronic wafer bonding structure 43, the light emission direction is changed by a reflective structure to be vertically upward, and the trench is wrapped by a light-transmitting layer, such that during the package process, the photonic integrated circuit wafer, the electronic integrated circuit chip, and the chip stacked structure 42 can all be protected by molding materials, which significantly increase strength and can also avoid contamination of the light-emitting area during underfill or molding processes.

An embodiment of the present disclosure further provides a chip package structure formed using the aforementioned package method, as shown in FIG. 14, the chip package structure of the present disclosure includes: a substrate 41, a chip stacked structure 42, and an optoelectronic wafer bonding structure 43.

The surface of the substrate 41 includes a first package area 411 and a second package area 412.

The chip stacked structure 42 is arranged on the first package area 411, and the optoelectronic wafer bonding structure 43 is arranged on the second package area 412, and the optoelectronic wafer bonding structure 43 uses the optoelectronic wafer bonding structure of the embodiments illustrated in FIGS. 8 to 9 of the present disclosure; for a detailed description, reference may be made to the preceding text and it will not be repeated herein.

In some embodiments, the substrate 41 is a silicon interposer. In the chip package method described in the present disclosure, a chip-wafer hybrid bonding structure between the electronic integrated circuit chip and the photonic integrated circuit chip is formed in advance, and during the package process, an additional substrate 41 is used as a 2.5D silicon interposer, which can avoid the problem of the electronic integrated circuit chip being incompatible with production lines when used as a 2.5D silicon.

In some embodiments, the chip stacked structure 42 includes memory (Memory). In the present embodiment, the memory is high-bandwidth memory (HBM).

In some embodiments, the chip package structure further includes a molding body 44 and optical fibers 45 formed on the surface of the substrate 41, and the molding body 44 covers the chip stacked structure 42 and the optoelectronic wafer bonding structure 43 and exposes the upper surfaces of the chip stacked structure 42 and the optoelectronic wafer bonding structure 43.

The molding body 44, as an important component of the entire package structure, typically uses polymeric materials such as epoxy resin, etc. The main function of the molding body 44 is to significantly enhance the overall strength of the package body and protect components from contamination. In practical applications, electronic products may face various complex usage environments, such as mechanical vibrations, collisions, etc. The molding body 44 can uniformly disperse external forces and prevent damage to internal components such as photonic integrated circuit chips and electronic integrated circuit chips, etc., so that the reliability and durability of the product is greatly improved.

Due to the reflective structure and the light-transmitting layer are provided in the light-emitting area of the optoelectronic wafer bonding structure 43, the light emission direction is changed by the reflective structure to be vertically upward, and the trench is wrapped by the light-transmitting layer, such that during the package process, the photonic integrated circuit wafer, the electronic integrated circuit chip, and the chip stacked structure 42 can all be protected by molding materials, which significantly increase strength and can also avoid contamination of the light-emitting area during underfill or molding processes.

The optical fiber 45 is soldered to the optical fiber soldering area. The optical fiber soldering area 250 is used to be connected with optical fibers during subsequent package processes, the optoelectronic wafer bonding structure and other optical devices, optical network equipment, etc., are connected together to achieve the integration and construction of optical communication systems.

In some embodiments, solder balls 410 are arranged on the lower surface S5 of the substrate 41 to connect to external circuits, thereby achieving electrical connections with external devices.

The above technical solution forms a chip-wafer hybrid bonding structure between the electronic integrated circuit chip and the photonic integrated circuit wafer in advance, during the package process, it can avoid the problem of the electronic integrated circuit chip being incompatible with production lines when used as a 2.5D silicon.

Furthermore, in the optoelectronic wafer bonding structure 43, the light emission direction is changed by a reflective structure to be vertically upward, and the trench is wrapped by a light-transmitting layer, such that during the package process, the photonic integrated circuit wafer, the electronic integrated circuit chip, and the chip stacked structure 42 can all be protected by molding materials, which significantly increase strength and can also avoid contamination of the light-emitting area during underfill or molding processes.

It should be noted that the references in the description “an embodiment,” “embodiment,” “exemplary embodiment,” “some embodiments,” etc., indicate that the described embodiments may include specific features, structures, or characteristics, but each embodiment may not necessarily include this specific feature, structure, or characteristic. Moreover, such phrases may not necessarily refer to the same embodiment. Furthermore, when specific features, structures, or characteristics are described in conjunction with embodiments, whether explicitly described or not, it is within the knowledge of those skilled in the relevant art to achieve such features, structures, or characteristics in conjunction with other embodiments.

Generally, terms may be understood at least partially from their usage in the context. For example, the term “one or more” as used in the present article is at least partially dependent on the context and may be used to describe any features, structures, or characteristics in a singular sense, or may be used to describe any features, structures, or characteristics in a plural sense. Similarly, depending at least partially on the context, terms such as “a,” “a certain,” or “this” may also be understood as expressing singular usage or plural usage.

Furthermore, the term “based on” may be understood as not necessarily intended to express a set of exclusive factors, but may alternatively, also be at least partially dependent on the context, permit the existence of other factors that may not be explicitly described. It should also be noted in the present description that “connection/coupling” not only refers to the direct coupling of one component to another component, but also refers to the indirect coupling of one component to another component through an intermediate component.

It should be noted that the terms “include” and “have” and their variations referred to in the document of the present disclosure are intended to cover non-exclusive inclusions. The terms such as “first,” “second,” etc., are used to distinguish similar objects and are not necessarily used to describe a specific order or sequence, and it is appreciated that unless otherwise indicated in the context clearly, the data used in this way can be interchanged in appropriate circumstances.

Furthermore, the embodiments of the present disclosure and features in the embodiments may be combined with each other without conflict. Furthermore, in the above explanation, descriptions of well-known components and technologies have been omitted to avoid unnecessary confusion of the concepts of the present disclosure. In the above embodiments, each embodiment focuses on illustrating differences from other embodiments, and the same/similar parts between the embodiments can be mutually referenced.

The above is only the embodiments of the present disclosure, it should be noted that those skilled in the art may also make several improvements and refinements without departing from the principles of the present disclosure, and these improvements and refinements should also be considered as the protection scope of the present disclosure.

What is claimed is:

1. An optoelectronic wafer bonding method, comprising:
providing a photonic integrated circuit wafer, wherein the photonic integrated circuit wafer comprises a plurality of photonic integrated circuit chips, each photonic integrated circuit chip has a first area, a second area, and a third area arranged in sequence along a first direction, the first area is provided with a conductive structure, and the second area is provided with a waveguide extending along the first direction;
forming a trench in the third area, and a sidewall of the trench exposes the waveguide;
providing an electronic integrated circuit chip and bonding a lower surface of the electronic integrated circuit chip to an upper surface of one of the photonic integrated circuit chips on the photonic integrated circuit wafer, wherein the electronic integrated circuit chip is electrically connected to the conductive structure;
arranging a reflective structure within the trench, wherein a light emitted from the waveguide is reflected by the reflective structure and then emitted along a second direction, wherein the second direction is perpendicular to the first direction; and
filling the trench with a light-transmitting material to form a light-transmitting layer covering the reflective structure, wherein the light emitted from the waveguide is reflected by the reflective structure and then emitted along the second direction, and propagates in the light-transmitting layer.

2. The method according to claim 1, wherein the conductive structure further comprises:
a first conductive solder pad arranged on the upper surface of the one of the photonic integrated circuit chips; and
a through-silicon-via, wherein one end of the through-silicon-via is electrically connected to the first conductive solder pad, another end of the through-silicon-via extends perpendicular to the upper surface of the one of the photonic integrated circuit chips toward an interior of the one of the photonic integrated circuit chips.

3. The method according to claim 1, wherein the light-transmitting layer also covers the upper surface of the one of the photonic integrated circuit chips.

4. The method according to claim 1, wherein the filling the trench with the light-transmitting material to form the light-transmitting layer covering the reflective structure further comprises:
providing an optical fiber soldering area on a surface of the light-transmitting layer, wherein the light emitted from the waveguide is reflected by the reflective structure and then emitted along the second direction, and propagates in the light-transmitting layer to the optical fiber soldering area.

5. The method according to claim 1, wherein the arranging the reflective structure within the trench further comprises:
providing a reflective structure, wherein the reflective structure comprises an inclined surface, and a reflective layer is arranged on the inclined surface; and
arranging the reflective structure within the trench, wherein the reflective layer is opposed to the waveguide, and the light emitted from the waveguide is reflected by the reflective layer and then emitted along the second direction.

6. The method according to claim 1, wherein the arranging the reflective structure within the trench further comprises:
filling the trench with a polymer base material and performing photolithography to form the reflective structure, wherein the reflective structure comprises an inclined surface opposite to the waveguide; and
arranging a reflective layer on the inclined surface.

7. The method according to claim 1, wherein the forming the trench in the third area further comprises:
retaining a part of a base material in the third area to form the reflective structure, wherein the reflective structure comprises an inclined surface opposite to the waveguide; and
forming a reflective layer on the inclined surface.

8. The method according to claim 5, wherein the reflective layer is a metal layer.

9. The method according to claim 1, further comprising:
providing a plurality of electronic integrated circuit chips;
bonding each lower surface of the plurality of electronic integrated circuit chips to each upper surface of the respective photonic integrated circuit chip on the photonic integrated circuit wafer, respectively; and
forming the reflective structure and the light-transmitting layer within the trench of each of the photonic integrated circuit chips.

10. The method according to claim 9, further comprising:
thinning a lower surface of the photonic integrated circuit wafer, such that one end of a through-silicon-via is exposed from the lower surface of the photonic integrated circuit wafer.

11. The method according to claim 10, wherein the thinning the lower surface of the photonic integrated circuit wafer further comprises:
bonding an auxiliary wafer on a surface of the light-transmitting layer;
thinning the lower surface of the photonic integrated circuit wafer, such that the one end of the through-silicon-via is exposed from the lower surface of the photonic integrated circuit wafer;
arranging solder balls on the lower surface of the photonic integrated circuit wafer; and
removing the auxiliary wafer.

12. The method according to claim 10, wherein after the thinning the lower surface of the photonic integrated circuit wafer, the method further comprises:
dicing the photonic integrated circuit wafer to obtain a plurality of independent optoelectronic wafer bonding structures.

13. The method according to claim 1, wherein the light-transmitting layer covers an upper surface of the reflective structure, or the upper surface of the reflective structure is flush with an upper surface of the light-transmitting layer.

14. An optoelectronic wafer bonding structure, comprising:
a photonic integrated circuit chip comprising a first area, a second area, and a third area arranged in sequence along a first direction, wherein the first area is provided with a conductive structure, and the second area is provided with a waveguide extending along the first direction, and the third area is provided with a trench, and a sidewall of the trench exposes the waveguide;
an electronic integrated circuit chip, wherein a lower surface of the electronic integrated circuit chip is bonded to an upper surface of the photonic integrated circuit chip, and the electronic integrated circuit chip is electrically connected to the conductive structure;
a reflective structure arranged within the trench, configured to reflect light emitted from the waveguide along a second direction, wherein the second direction is perpendicular to the first direction; and
a light-transmitting layer filling the trench and covering the reflective structure, such that the light reflected along the second direction propagates in the light-transmitting layer.

15. The optoelectronic wafer bonding structure according to claim 14, wherein the conductive structure further comprises:
a first conductive solder pad arranged on the upper surface of the photonic integrated circuit chip; and
a through-silicon-via, wherein one end is electrically connected to the first conductive solder pad, and another end is exposed from a lower surface of the photonic integrated circuit chip.

16. The optoelectronic wafer bonding structure according to claim 14, wherein a lower surface of the photonic integrated circuit chip is further provided with solder balls.

17. The optoelectronic wafer bonding structure according to claim 14, wherein the reflective structure comprises:
an inclined surface; and
a reflective layer arranged on the inclined surface, wherein the reflective layer and the waveguide are arranged opposite to each other, such that light emitted from the waveguide is reflected by the reflective layer and then emitted along the second direction.

18. The optoelectronic wafer bonding structure according to claim 14, wherein the light-transmitting layer further covers the upper surface of the electronic integrated circuit chip.

19. The optoelectronic wafer bonding structure according to claim 14, wherein the light-transmitting layer covers an upper surface of the reflective structure, or the upper surface of the reflective structure is flush with an upper surface of the light-transmitting layer.

20. The optoelectronic wafer bonding structure according to claim 14, wherein a surface of the light-transmitting layer is provided with an optical fiber soldering area, and light emitted from the waveguide is reflected by the reflective structure and then emitted along the second direction, and propagates in the light-transmitting layer to the optical fiber soldering area.
